(19) United States
(12) Patent Application Publication
(10) Pub. No.: US 2025/0003701 A1
(43) Pub. Date: Jan. 2, 2025

(54) INTERCONNECTOR FOR A HEAT EXCHANGER

(71) Applicant: VALEO SYSTEMES THERMIQUES, La Verriere (FR)

(72) Inventors: Henry BOYD, Auburn Hills, MI (US); David TROY, Auburn Hills, MI (US)

(73) Assignee: VALEO SYSTEMES THERMIQUES, La Verriere (FR)

(21) Appl. No.: 18/342,794

(22) Filed: Jun. 28, 2023

(51) Int. Cl. F28F 9/02; F28F 9/26

(52) U.S. Cl. CPC F28F 9/0248; F28F 9/0253; F28F 9/26; F28F 2230/00; H05K 7/20854

(57) ABSTRACT

An interconnector for a heat exchanger comprising a body with an upper inlet and a lower inlet connected by an inlet conduit, an upper outlet and a lower outlet connected by an outlet conduit, an external inlet communicated with the inlet conduit, an external outlet communicated with the outlet conduit, wherein the inlet conduit and the outlet conduit are fluidically isolated with respect to each other within the interconnector.

### TECHNICAL FIELD

The invention relates to an interconnector for a heat exchanger, in particular for a heat exchanger for an electronic control unit, applicable in automotive field.

### BACKGROUND OF THE INVENTION

Electronic control units are known to require thermal management. Integrated circuits, or other electronic or electric components, generate heat during operation. In case of integrated circuits, the power is dissipated on a small surface. The heat generated this way needs to be effectively evacuated, especially when the components operate under high loads. High performance units require dedicated cooling devices to enable their effective operation. One known way of addressing the issue is to utilize air for direct cooling of the heat sources.

Automotive industry increasingly depends on high performance electronic control units to ensure safe and effective operation of vehicles. More and more of electronic control units, in various forms and configurations, are utilized to perform functions such as controlling the vehicle's battery systems, handling the driver assistance systems or performing autonomous driving function.

There is a need to provide an effective heat exchange solution, which could be used for thermal management of an electronic control unit, in particular one used in a vehicle.

### SUMMARY OF THE INVENTION

The object of the invention is, among others, an interconnector for a heat exchanger comprising a body with an upper inlet and a lower inlet connected by an inlet conduit, an upper outlet and a lower outlet connected by an outlet conduit, an external inlet communicated with the inlet conduit, an external outlet communicated with the outlet conduit, wherein the inlet conduit and the outlet conduit are fluidically isolated with respect to each other within the interconnector.

Preferably, the upper inlet and the lower inlet are concentric.

Preferably, the upper outlet and the lower outlet are concentric.

Preferably, the external inlet is arranged perpendicular to the upper inlet.

Preferably, the external outlet is arranged perpendicular to the upper outlet.

Preferably, the external inlet is arranged parallel to the external outlet.

Preferably, the external inlet faces away from the external outlet.

Preferably, the external inlet is concentric with the external outlet.

Preferably, the body includes a first external face on which the external inlet is arranged, a second external face on which the external outlet is arranged, and a middle recess arranged between the first external face and the second external face and extending between the inlet conduit and the outlet conduit.

Preferably, the body includes an upper face with an upper recess, the upper inlet and the upper outlet being arranged within the upper recess.

Preferably, the body includes a lower face with a lower recess, the lower inlet and the lower outlet being arranged within the lower recess.

Another object of the invention is a heat exchanger comprising: a first tube with a first tube inlet and a first tube outlet interconnected by a first tube channel; a second tube with a second tube inlet and a second tube outlet interconnected by a second tube channel; an interconnector having a body with an upper inlet and a lower inlet connected by an inlet conduit, an upper outlet and a lower outlet connected by an outlet conduit, an external inlet communicated with the inlet conduit, an external outlet communicated with the outlet conduit; wherein the inlet conduit and the outlet conduit are fluidically isolated with respect to each other within the interconnector, the interconnector being located between the first tube and the second tube, the interconnector being connected to the first tube inlet by the upper inlet and to the first tube outlet by the upper outlet, the interconnector being connected to the second tube inlet by the lower inlet and to the second tube outlet by the lower outlet.

Preferably, the external inlet faces away from the first tube and the second tube.

Preferably, the external outlet faces away from the first tube and the second tube.

Preferably, the interconnector has an upper inlet collar inserted into an upper inlet collar opening of the interconnector, the upper inlet collar connecting the upper inlet with the first tube inlet.

Preferably, the interconnector has an integrated lower inlet collar connecting the lower inlet with the second tube inlet.

Preferably, an upper collar plate, with an integrated upper inlet collar and an integrated upper outlet collar, is attached to the interconnector, the upper inlet collar being inserted into an upper inlet collar opening of the interconnector and connecting the upper inlet with the first tube inlet, with the upper outlet collar being inserted into an upper outlet collar opening of the interconnector and connecting the upper outlet with the first tube outlet.

Preferably, a lower collar plate, with an integrated lower inlet collar and an integrated lower outlet collar, is attached to the interconnector, the lower inlet collar being inserted into a lower inlet collar opening of the interconnector and connecting the lower inlet with the second tube inlet, with the lower outlet collar being inserted into a lower outlet collar opening of the interconnector and connecting the lower outlet with the second tube outlet.

Preferably, the interconnector is located at ends of the first tube and the second tube.

Preferably, the second tube includes an additional second tube inlet and an additional second tube outlet interconnected by the second tube channel, the heat exchanger further comprising a third tube with a third tube inlet and a third tube outlet interconnected by a third tube channel, an additional interconnector including a body with an upper inlet and a lower inlet connected by an inlet conduit, an upper outlet and a lower outlet connected by an outlet conduit, wherein the inlet conduit and the outlet conduit are fluidically isolated with respect to each other within the additional interconnector, the additional interconnector being located between the second tube and the third tube, the additional interconnector being connected to the additional second tube inlet by the upper inlet of the additional interconnector and to the additional second tube outlet by the upper outlet of the additional interconnector, the additional interconnector being connected to the third tube inlet by the lower inlet of the additional interconnector and to the third tube outlet by the lower outlet of the additional interconnector.

Preferably, the body of the additional interconnector includes an external inlet communicated with the inlet conduit of the additional interconnector and an external outlet communicated with the conduit of the outlet additional interconnector.

### BRIEF DESCRIPTION OF DRAWINGS

The present invention will be described in greater detail below with reference to the drawings. In the drawings:

FIG. 1 shows a heat exchanger assembly with heat source modules in a perspective view;

FIG. 2 shows schematically extension planes of select heat exchanger assembly components;

FIG. 3 shows a heat exchanger assembly of FIG. 1 in an exploded view;

FIG. 4 shows a heat exchanger assembly in a perspective view;

FIG. 5 shows a chassis with a heat exchanger in a perspective view;

FIG. 6 shows a chassis in a perspective view from above;

FIG. 7 shows a chassis in a perspective view from below;

FIG. 8 shows a heat source module in form of a cartridge in a perspective view from the bottom;

FIG. 9 shows a heat exchanger and a heat source module in an exploded view;

FIG. 10 shows a heat exchanger in a perspective view from above;

FIG. 11 shows a heat exchanger in a perspective view from below;

FIG. 12 shows another example a heat exchanger in a perspective view from above;

FIG. 13 shows another example a heat exchanger in a perspective view from above;

FIG. 14 shows another example a heat exchanger in a perspective view from above; FIG. 15 shows another example a heat exchanger in a perspective view from below;

FIG. 16 shows another example a heat exchanger in a perspective view from below;

FIG. 17 shows another example a heat exchanger in a perspective view from above;

FIG. 18 shows a heat exchanger in a side view;

FIG. 19 shows an example of a first tube;

FIG. 20 shows an example of a second tube;

FIG. 21 shows an example of a first tube with attachments;

FIG. 22 shows an example of an attachment;

FIG. 23 shows another example of an attachment;

FIG. 24 shows an example of a second tube with attachments;

FIG. 25 shows another example of an attachment;

FIG. 26 shows another example of an attachment;

FIG. 27 shows a partial side view of an attachment in detail;

FIG. 28 shows another side view of an attachment in detail;

FIG. 29 shows an example of a partial cross-sectional view of a shaped plate with an attachment;

FIG. 30 shows a cross-section view of the first tube of FIG. 20;

FIG. 31 shows another example a heat exchanger in an exploded view from above;

FIG. 32 shows another example a heat exchanger in an exploded view from below;

FIG. 33 shows an example of an interconnector from the front;

FIG. 34 shows another example of an interconnector in an exploded view from the front;

FIG. 35 shows another example of an interconnector in an exploded view from the front;

FIG. 36 shows an example of an interconnector with visualized inner channels;

FIG. 37 shows an example of an interconnector from the back;

FIG. 38 shows another example of an interconnector from the front;

FIG. 39 shows a collar plate of an interconnector;

FIG. 40 shows another example of an interconnector from the front;

FIG. 41 shows another example of an interconnector from the front;

FIG. 42 shows the interconnector of FIG. 40 with an external connector from the top;

FIG. 43 shows another example of an interconnector from the front;

FIG. 44 shows another example of an interconnector with visualized inner channels;

FIG. 45 shows another example of an interconnector from the front;

FIG. 46 shows the interconnector of FIG. 44 with two external connectors from the top;

FIG. 47 shows example of an additional interconnector;

FIG. 48 shows another example of a heat exchanger in a perspective view; and

FIG. 49 shows the heat exchanger of FIG. 48 with external connectors.

### DETAILED DESCRIPTION OF THE INVENTION

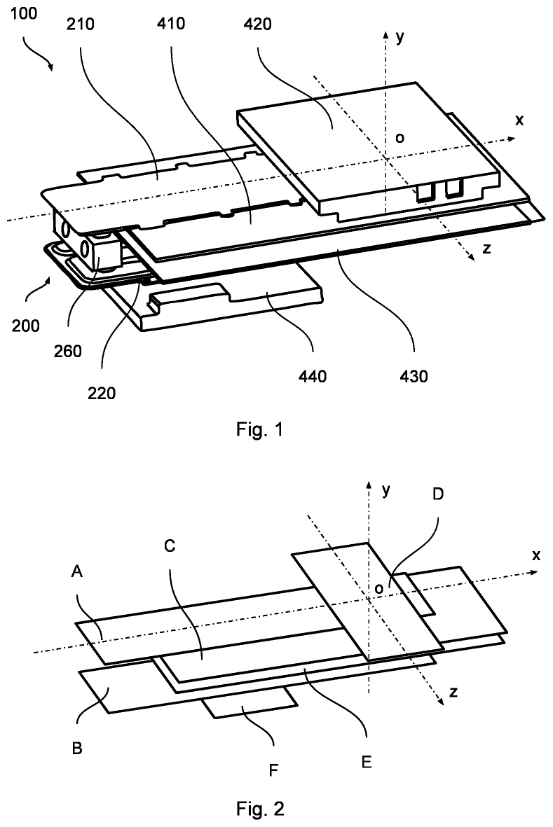

In order to simplify the description of the invention, a Cartesian reference is formed (o, x, y, z), and the direction o-x is defined as being the direction of the length, o-y is the direction of the height, and o-z is the direction of the width, as shown in FIGS. 1 and 2.

FIG. 1 shows a heat exchanger assembly 100 with a heat exchanger 200 and a plurality of heat source modules 410, 420, 430, 440 in a perspective view. The heat exchanger 200 includes a first tube 210 for a heat exchange fluid. The heat exchange fluid flows through the heat exchanger 200, in particular through the first tube 210, and enables heat exchange between the heat exchanger 200 and any heat sources in contact with it. The heat exchange fluid can be a refrigerant (such as R134A, R-1234YF or R744) or a coolant (e.g. glycol-water mixture).

The heat exchanger 200 can further include a second tube 220 for a heat exchange fluid, connected fluidically to the first tube 210. The first tube 210 and the second tube 220 can be connected by one or more interconnectors 260 enabling fluid flow therebetween.

The heat exchanger assembly 100 includes at least a first heat source module 410. In the embodiment shown in FIG. 1, the heat exchanger assembly 100 includes the first heat source module 410, a second heat source module 420, a third heat source module 430 and a fourth heat source module 440.

The first heat source module 410 abuts the first tube 210, so that heat from the first heat source module 410 can be dissipated to the first tube 210.

In the shown embodiment, the first and second heat source modules 410, 420 abut the first tube 210. The second tube 220 is abutted by the third and fourth heat source modules 430, 440. In other words, the first tube 210 is sandwiched between the first and second heat source modules 410, 420, while the second tube 220 is sandwiched between the third heat source module 430 and the fourth heat source module 440. By the term “sandwiched” it is meant that the first tube 210 and second tube 220 are in contact with and are located between respective heat source modules, taking into account presence of any thermal paste that could be used between their surfaces to improve heat exchange.

FIG. 2 shows schematically examples of extension planes of select components of the heat exchanger assembly 100. The first tube 210 extends within a first tube extension plane A. The second tube 220 extends within a second tube extension plane B. The first heat source module 410 extends within a first heat source module extension plane C. The second heat source module 420 extends within a second heat source module extension plane D. The third heat source module 430 extends within a third heat source module extension plane E. The fourth heat source module 440 extends within a fourth heat source module extension plane F. By “extension within an extension plane”, it is meant here that two dimensions of the three-dimensional component are significantly greater than the third dimension, where the two dimensions are measured within said extension plane. The third dimension is measured perpendicular to the extension plane. In other words, a component extending within an extension plane is a generally flat component, the height of which is relatively small compared to its width and length. Preferably, all extension planes A, B, C, D, E and F extend in parallel to each other.

In the shown embodiment, the first tube 210 and the second tube 220 extend predominantly along axis X and to a lesser degree along axis Z, meaning their length is greater than their width. Their height is substantially smaller than the two other dimensions.

The first heat source module 410 and the third heat source module 430 similarly extend predominantly along axis X and to a lesser degree along axis Z, meaning their length is greater than their width. Their height is substantially smaller than the two other dimensions.

The second heat source module 420 and the fourth heat source module 440 extend predominantly along axis Y and to a lesser degree along axis Z, meaning their width is greater than their length (the opposite arrangement is also envisaged). Their height is substantially smaller than the two other dimensions.

It should be noted that there can be a plurality of the second heat source modules 420 arranged along the first tube 210, as well as a plurality of fourth heat source modules 440 arranged along the second tube 220. Similarly, a plurality of the first heat source modules 410 and the third heat source modules 430 could be arranged along the first and second tubes 210, 220, depending on the configuration of the unit.

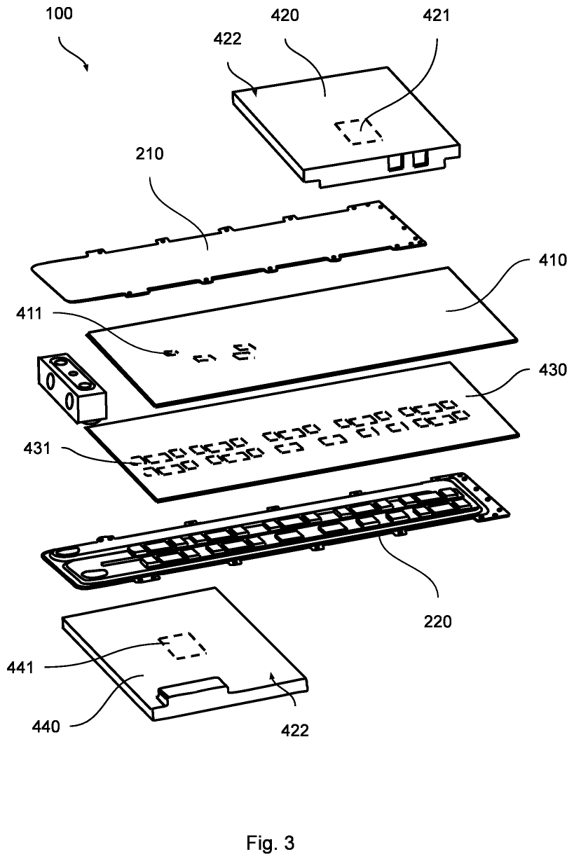

FIG. 3 shows a heat exchanger assembly 100 of FIG. 1 in an exploded view. The first heat source module 410 includes at least one first heat source 411. In the shown embodiment, the first heat source module 410 includes a plurality of first heat sources 411. Preferably, the plurality of first heat sources 411 extends parallel to the predominant extension axis of the first tube 210 so that this single first tube 210 can address the heat exchange needs of the whole first heat source module 410. In one embodiment, the first heat source module 410 is a PCB board. The first heat sources 411 can be individual integrated circuits.

The second heat source module 420 includes at least one second heat source 421.

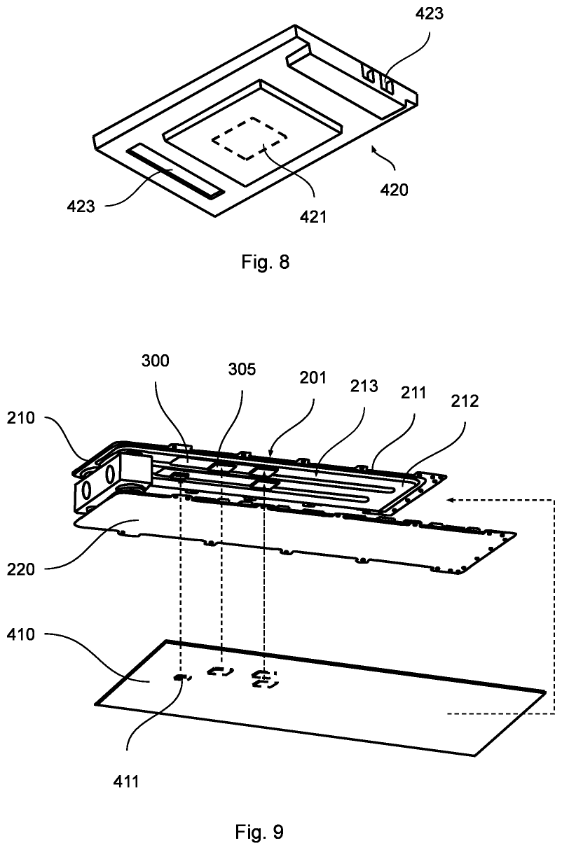

In the shown embodiment, the second heat source module 420 is in form of a cartridge 422. as it will be shown in detail in FIG. 8. In one embodiment, the second heat source module 420 is in form of a cartridge 422 in which a PCB board with at least one integrated circuit is located.

The third heat source module 430 includes at least one third heat source 431. In the shown embodiment, the third heat source module 430 includes a plurality of third heat sources 431. Preferably, the plurality of the third heat sources 411 extends parallel to the predominant extension axis of the second tube 220 so that this single second tube 220 can address the heat exchange needs of the whole third heat source module 430. In one embodiment, the third heat source module 430 is a PCB board. The third heat sources 431 can be integrated circuits.

The fourth heat source module 440 includes at least one fourth heat source 441. In one embodiment, the fourth heat source module 440 is in form of a cartridge 422 in which a PCB board with at least one integrated circuit is located.

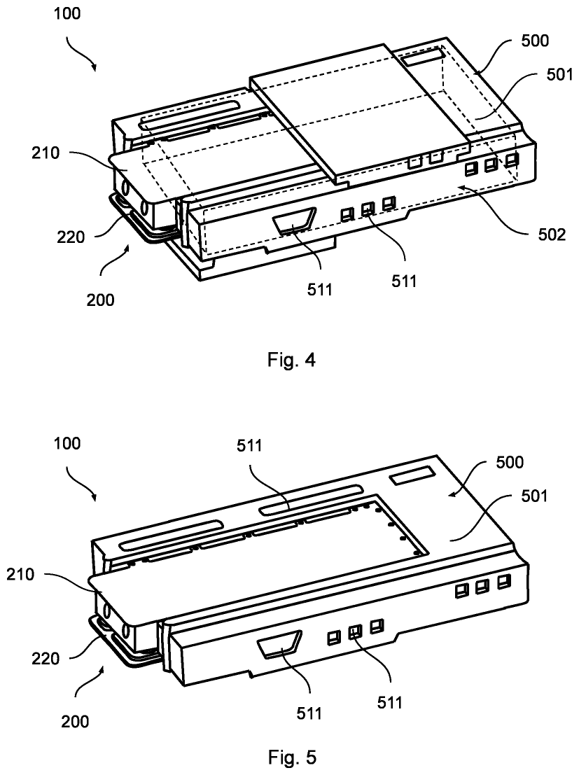

FIG. 4 and FIG. 5 respectively show a heat exchanger assembly 100 and a chassis 500 with a heat exchanger 200 in a perspective view. The heat exchanger assembly 100 can include a chassis 500 serving as a mounting point for all the components, as well as enabling integration of the heat exchanger assembly 100 to other structures, such as a dedicated rack or a vehicle structure.

The chassis 500 preferably includes a housing 501, which can define an internal volume 502. The first heat source module 410 can be located within the internal volume 502. Preferably, the third heat source module 430 is also located inside the internal volume 502. The chassis 500 with the housing 501 allows to have the first and third heat source modules 410, 430 in form of PCBs without other protective arrangements, as the housing 501 can be configured to constitute a standalone enclosure protecting the internal components from outside detrimental factors as moisture, debris or moving elements of the vehicle. The housing 501 can include housing apertures 511 enabling connectors (not shown) of the first and third heat source modules 410, 430 to be exposed so that they can be connected to external signal and/or power lines, as well as connection between the second and fourth heat source modules 420, 440 to the components located inside of the housing 501.

In the shown embodiment, the first tube 210 is located externally with respect to the housing 501. The second tube 220 can be located externally with respect to the housing 501 as well. Consequently, any heat source modules external to the housing 501 can also be cooled by the heat exchanger 200 of the heat exchanger assembly 100. In particular, the second heat source module 420 can be attached to the chassis 500 externally with respect to the housing 501. Similarly, the fourth heat source module 440 can be attached to the chassis 500 externally with respect to the housing 501.

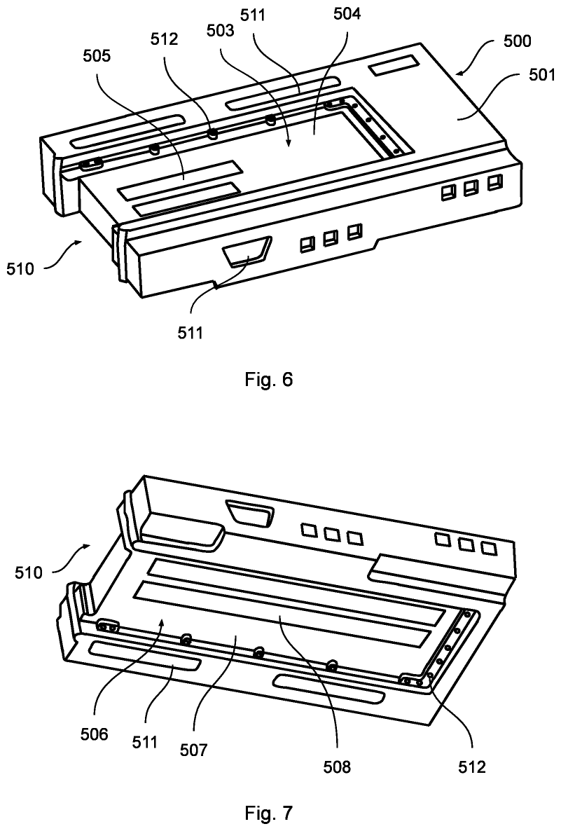

FIG. 6 and FIG. 7 respectively show the chassis 500 without the heat exchanger 200 in a perspective view from above and below. The housing 501 of the chassis 500 can include a primary slot 503 for the first tube 210. The primary slot 503 can at least partially envelop the first tube 210. In other words, the primary slot 503 constitutes a depression within the housing 501 in which the first tube 210 can be placed. The top portion of the first tube 210 can thus be flush with the housing 501. The primary slot 503 allows providing a compact assembly, in particular when the second heat source 420 is also attached to the housing 501 of the chassis 500 as shown above.

The housing 501 can have a primary separation wall 504 between the first tube 210 and the first heat source module 410. As explained in detail in relation to further figures, the heat exchanger 200 can include attachments 300 attached to and protruding substantially perpendicularly from the first tube 210 and/or the second tube 220. In such case, the primary separation wall 504 can include at least one primary attachment opening 505 through which such attachment 300 protrudes. In the shown embodiment, there are two attachments 300 placed on the first tube 210. Consequently, there are two primary attachment openings 505 as well. The two primary attachment openings 505 can be of different sizes to accommodate differently sized attachments 300.

In one embodiment, the housing 501 has an interconnector cut-out 510 at least partially enveloping one or more interconnectors 260 extending between the first tube 210 and the second tube 220. In other words, the interconnector cut-out 510 constitutes a depression within the housing 501 in which said one or more interconnectors 260 can be placed. This allows improving compactness of the assembly.

As shown in FIG. 7, the housing 501 can have a secondary slot 506 for the second tube 220. which can at least partially envelope the second tube 220 analogously to the primary slot 503 in relation to the first tube 210.

The housing 501 can have a secondary separation wall 507 between the second tube 220 and the third heat source module 430. The secondary separation wall 507 can include one or more secondary attachment openings 508 through which any attachment 300 of the second tube 220 can protrude. The secondary attachment openings 508 can be of different sizes to accommodate differently sized attachments 300.

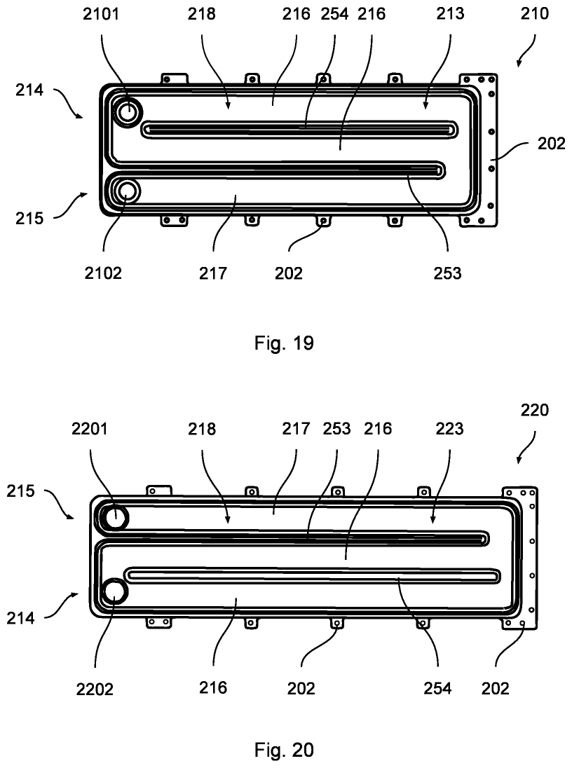

The housing 501 can include housing attachment points 512 to enable direct fixation of the first tube 210 and second tube 220 if needed. For example, the housing attachment points 512 can be in form of a base with opening for a screw, while the first and second tubes 210, 220 can have corresponding tube attachment tabs 202 (as shown in FIGS. 18, 19) with openings as well so that the components can be fixed together by means of screws.

FIG. 8 shows a heat source module, in this case the second heat source module 420, in form of a cartridge 422 in a perspective view from the bottom. The second heat source module 420 includes a second heat source 421, for example a PCB board with one or more integrated circuits. In the shown embodiment, the second heat source module 420 encapsulates the second heat source 421. The cartridge 422 can be a case defining a closed volume inside of which the second heat source 421 is located. Cartridge apertures 423 can be provided to enable connecting the second heat source module 420 to other components of the chassis 500 or external signal or power lines.

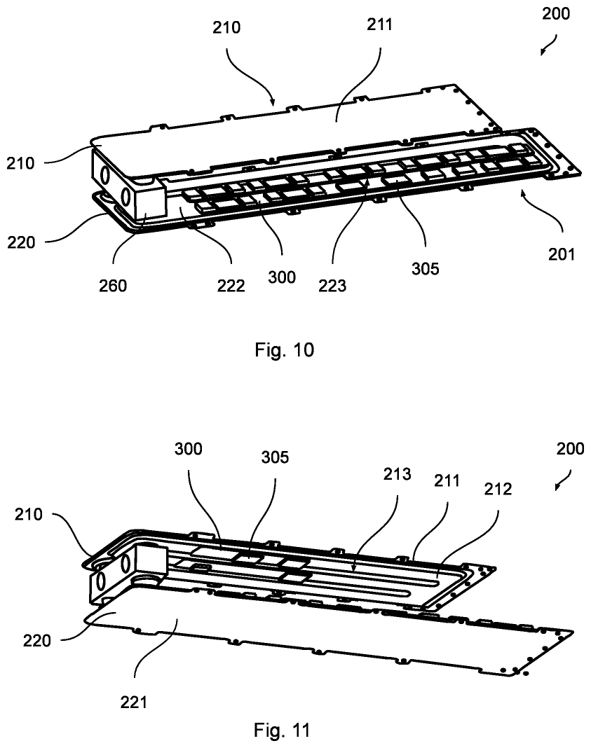

FIG. 9 shows a heat exchanger 200 and a heat source module, in this case the first heat source module 410, in an exploded view from below. The first heat source module 410, with a plurality of the first heat sources 411 is placed between the first tube 210 and the second tube 220, in contact with the first tube 210. The first tube 210 can be made of heat exchange plates 201. In the shown embodiment, the first tube 210 includes a first flat plate 211 (as better seen in FIG. 10) and a first shaped plate 212 connected to each other to form a first tube channel 2103 for the heat exchange fluid. In general, by a flat plate it is meant a plate which is generally flat and contributes to formation of any fluid channel by its flat portion. Since the first tube 210 includes attachments 300 with contact portions 305 for ensuring direct contact with first heat sources 411, an effective heat exchange can be provided. The second heat source module 420 can be abutting the first flat plate 211 so that heat dissipated from it can be received by the first tube 210.

FIGS. 10 and 11 respectively show the heat exchanger 200 in a perspective view from above and below. The second tube 220 can be made of heat exchange plates 201. In the shown embodiment, the second tube 220 includes has a second flat plate 221 and a second shaped plate 222 connected to each other to form a second tube channel 2203.

The first and second flat plates 211, 221 and the first and second shaped plate 212, 222 include fluid openings 250 (as better seen in FIGS. 18, 19) to enable fluid flow to and from the first and second tubes 220. In such case, the interconnectors 260 can connect respective openings 250.

Preferably, the second tube 220 includes one or more attachments 300 with a plurality of contact portions 305 exposed to the plurality of third heat sources 431. The attachments can be mounted on the second tube 220 adjacent to the second tube channel 2203.

In the shown embodiment, the first shaped plate 212 and the second shaped plate 222 face each other.

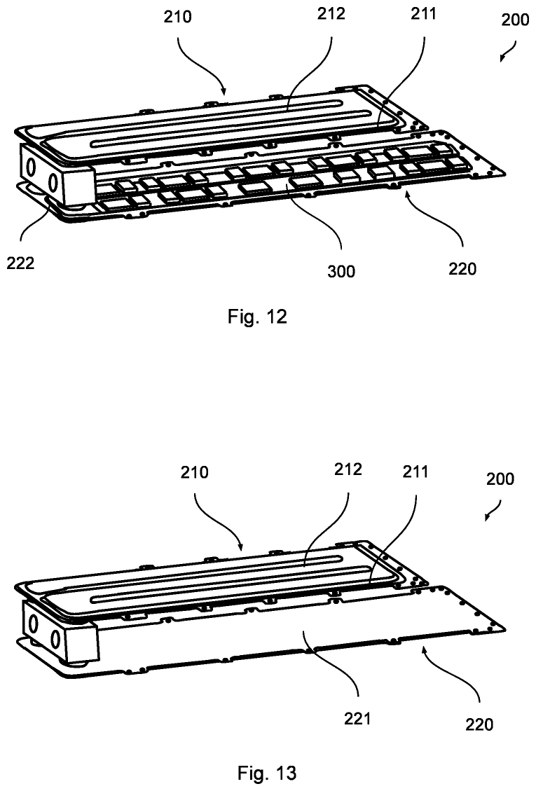

FIG. 12 shows another example a heat exchanger 200 in a perspective view from above, where the first shaped plate 212 faces away from the second shaped plate 222. Any of the first flat plate 211, the first shaped plate 212, the second flat plate 221 and the second shaped plate 222 can have one or more attachments 300 fixed thereto, depending on heat exchange needs and placement of specific heat sources. In this case, the first flat plate 211 and the second shaped plate 222 are equipped with attachments 300 to facilitate heat exchange with individual heat sources to be located in-between the first tube 210 and the second tube 220.

FIG. 13 shows another example a heat exchanger 200 in a perspective view from above, where the first flat plate 211 and the second flat plate 221 face each other. Any of the first flat plate 211, the first shaped plate 212, the second flat plate 221 and the second shaped plate 222 can have one or more attachments 300 fixed thereto, depending on heat exchange needs and placement of specific heat sources.

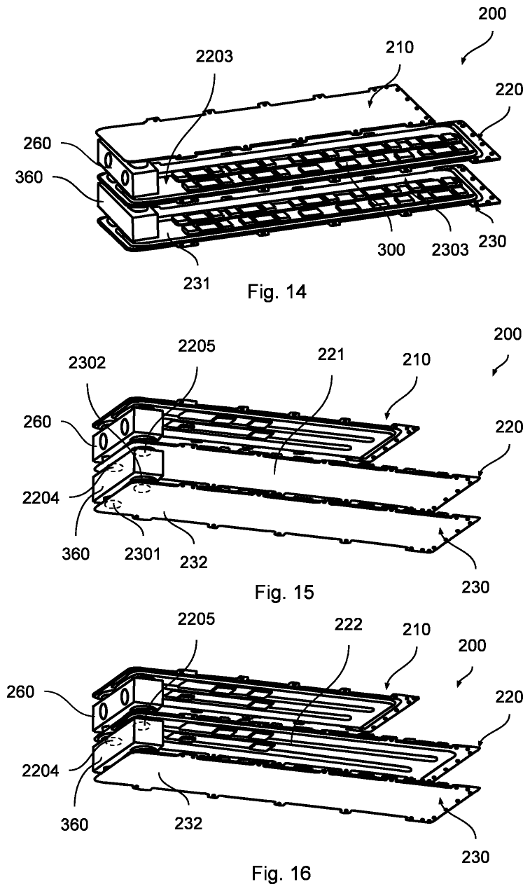

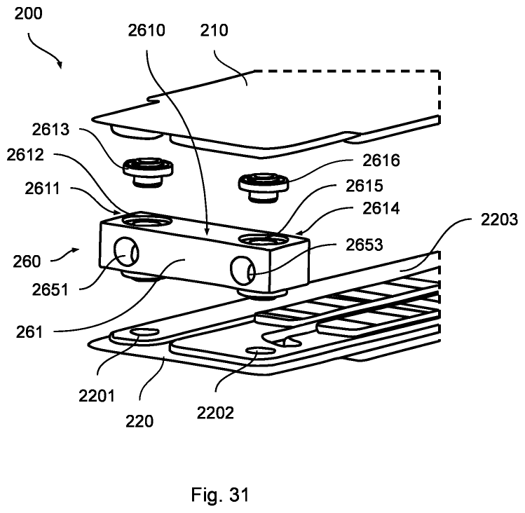

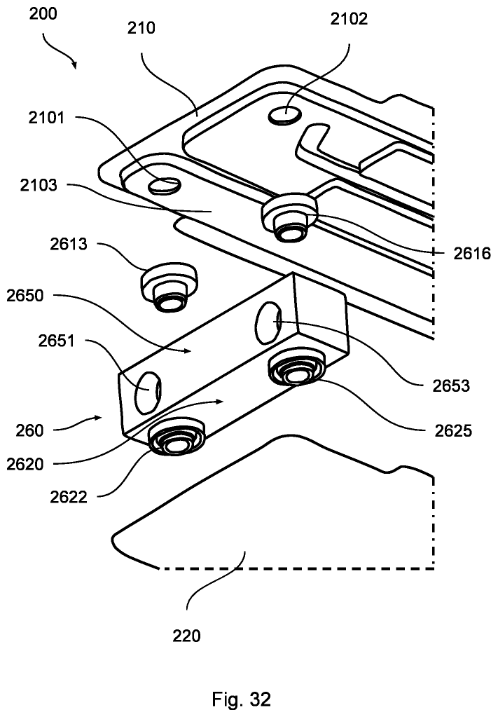

FIGS. 14 and 15 show another example a heat exchanger 200 in a perspective view respectively from above and below. The heat exchanger 200 can include a third tube 230 arranged in series with the first tube 210 and the second tube 220. In other words, the third tube 230 can be attached to the second tube 220, on its other side compared to the first tube 210. The third tube 230 can be connected to the second tube 220 by an additional interconnector 360. As explained in the context of FIGS. 31 and 32, the first tube 210 includes a first tube inlet 2101 and a first tube outlet 2102 interconnected by a first tube channel 2103, while the second tube 220 can include a second tube inlet 2201 and a second tube outlet 2202 interconnected by a second tube channel 2203.

The second tube 220 can include an additional second tube inlet 2204 and an additional second tube outlet 2205, for example placed on the opposite side of the second tube 220 compared with the second tube inlet 2201 and the second tube outlet 2202. The additional second tube inlet 2204 and the additional second tube outlet 2205 can be interconnected by the second tube channel 2203. The third tube 230 includes a third tube inlet 2301 and a third tube outlet 2302 interconnected by the third tube channel 2303.

The third tube 230 can include a third flat plate 231 and a third shaped plate 232 connected to each other to form the third fluid channel 2303, wherein the third flat plate 231 and the third shaped plate 232 include a third tube inlet 2301 and a third tube outlet 2302 to enable fluid flow to and from the third tube 230. An attachment 300 can be used for the third tube 230 in a same manner as for the first tube 210 and the second tube 220. In any case, the third tube 230 can have an analogous structure to the first tube 210 and/or the second tube 220. There can also be a plurality of third tubes 230 in addition to the first tube 210 and the second tube 220.

In the shown example, the third shaped plate 232 faces the second flat plate 221.

FIG. 16 shows another example a heat exchanger 200 in a perspective view from below. Compared to the example of the heat exchanger 200 of FIGS. 14 and 15, here the third shaped plate 232 faces the second shaped plate 222.

The heat exchanger can include an additional interconnector 360 with a body 261 having an upper inlet 2611 and a lower inlet 2621 connected by an inlet conduit 2801, and an upper outlet 2614 and a lower outlet 2624 connected by an outlet conduit 2802.

The inlet conduit 2801 and the outlet conduit 2802 can be fluidically isolated with respect to each other within the additional interconnector 360.

The additional interconnector 360 can be located between the second tube 220 and the third tube 230.

The additional interconnector 360 can be connected to the additional second tube inlet 2204 by the upper inlet 2611 of the additional interconnector 360 and to the additional second tube outlet 2205 by the upper outlet 2614 of the additional interconnector 360.

The additional interconnector 360 can be connected to the third tube inlet 2301 by the lower inlet 2621 of the additional interconnector 360 and to the third tube outlet 2302 by the lower outlet 2624 of the additional interconnector 360.

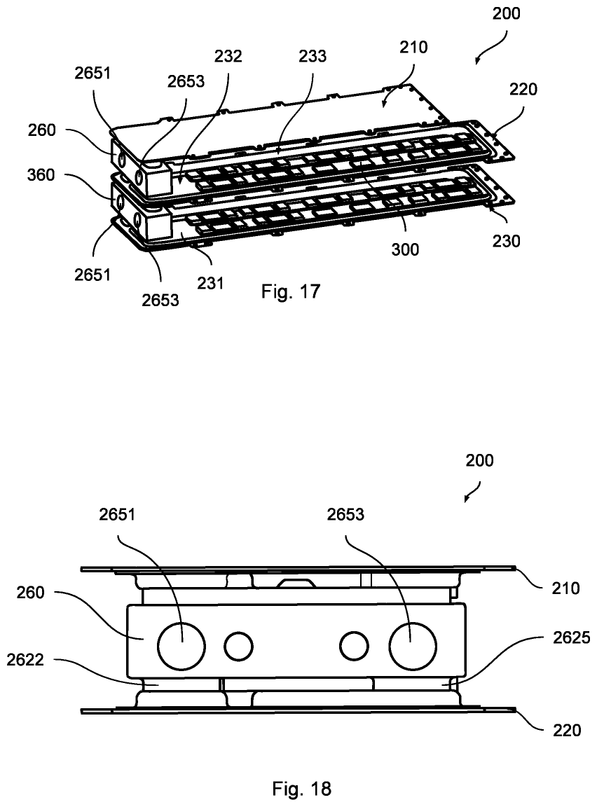

FIG. 17 shows another example a heat exchanger 200 in a perspective view from above. The body 261 of the additional interconnector 360 can include an external inlet 2651 communicated with the inlet conduit 2801 of the additional interconnector 360 and an external outlet 2653 communicated with the outlet conduit 2802 of the additional interconnector 360.

FIG. 18 shows the heat exchanger 200 of FIGS. 10 and 11 in a side view. The first tube 210 and the second tube 220 can be connected by an interconnector 260 to mechanically fix one to another and to enable heat exchange fluid to travel therebetween. In particular, the first tube inlet 2101, the first tube outlet 2102, the second tube inlet 2201 and the second tube outlet 2202 of the first tube 210 and the second tube 220 (shown in FIGS. 19 and 20) are connected by interconnector 260 to enable fluid flow therebetween.

FIG. 19 shows an example of a first tube 210. The first tube 210 includes a first tube channel 2103 to guide the heat exchange fluid through the first tube 210. The first tube 210 includes a first tube inlet 2101 and a first tube outlet 2102 for respectively introducing and egressing the heat exchange fluid from the first tube 210.

In the shown embodiment, the first tube channel 2103 forms a U-flow path having a first arm 214 and a second arm 215. The fluid openings 250 can be arranged at the opposite ends of the U-flow path.

In relation to FIG. 20 and the second tube 220, the second tube channel 2203 can form a U-flow path having a first arm 214 and a second arm 215. The fluid openings 250 can be arranged at the opposite ends of the U-flow path. The U-flow path of the first tube 210 can have a different length than the U-flow path of the second tube 220. In general, the first tube 210 can be shorter than the second tube 220. The first tube 210 can be longer than the second tube 220. The first tube 210 can also be of the same length as the second tube 220.

The first arm 214 can be split into at least two parallel sub-conduits 216. The second arm 215 can be formed by a single conduit 217. The split can be used to help balance the flow in the plate. It can also focus the flow to specific got spots to achieve better heat transfer coefficient.

The first arm 214 can be separated from the second arm 215 by a first wall 253 extending away from the ends of the U-flow path. The at least two sub-conduits 216 can be separated from each other by a second wall 254 extending away from the ends of the U-flow path. The first wall 253 can extend farther away from the ends of the U-flow path than the second wall 254. This as well can help management of the heat exchange as explained above. Preferably, the at least two parallel sub-channels 216 terminate in common fluid openings 250.

In the shown embodiment, the first shaped plate 212 can include a stamped depression 218 forming together with the surface of the first flat plate 211 the first tube channel 2103. The stamped depression 218 can have a flat surface at the bottom, located away from the first flat plate 211.

FIG. 20 shows an example of a second tube 220. The second tube 220 includes a second tube channel 2203 to guide the heat exchange fluid throughout the second tube 220. The second tube 220 includes fluid openings 250 for introducing and egressing the heat exchange fluid from the second tube 220.

Preferably, one end of the second tube channel 2203 has two fluid openings 250 for enabling the fluid flow to the second tube 220, while the other end of the second tube channel 2203 has two fluid openings 250 for enabling the fluid flow out of the second tube 220. In such case, each pair of fluid openings 250 includes one fluid opening 250 in the second flat plate 221 and one fluid opening 250 in the second shaped plate 222.

In the shown embodiment, the second tube channel 2203 forms a U-flow path having a first arm 214 and a second arm 215. The fluid openings 250 can be arranged at the opposite ends of the U-flow path.

The second tube channel 2203 can form a U-flow path having a first arm 214 and a second arm 215. The fluid openings 250 can be arranged at the opposite ends of the U-flow path.

The first arm 214 can be split into at least two parallel sub-conduits 216. The second arm 215 can be formed by a single conduit 217.

The first arm 214 can be separated from the second arm 215 by a first wall 253 extending away from the ends of the U-flow path. The at least two sub-conduits 216 can be separated from each other by a second wall 254 extending away from the ends of the U-flow path. The first wall 253 can extend farther away from the ends of the U-flow path than the second wall 254. Preferably, the at least two parallel sub-channels 216 terminate in common fluid openings 250.

In the shown embodiment, the second shaped plate 222 can include a stamped depression 218 forming together with the surface of the second flat plate 221 the second tube channel 2203. The stamped depression 218 can have a flat surface at the bottom, located away from the second flat plate 221.

In the shown embodiment, the second shaped plate 222 includes fluid openings 250 for the fluid to enable fluid flow to and from the second tube 220, while the second flat plate 221 lacks any fluid openings 250 for the fluid.

As described above, an inlet spigot 251 and an outlet spigot 252 for the heat exchange fluid can be attached to the openings 250 of the first tube 210.

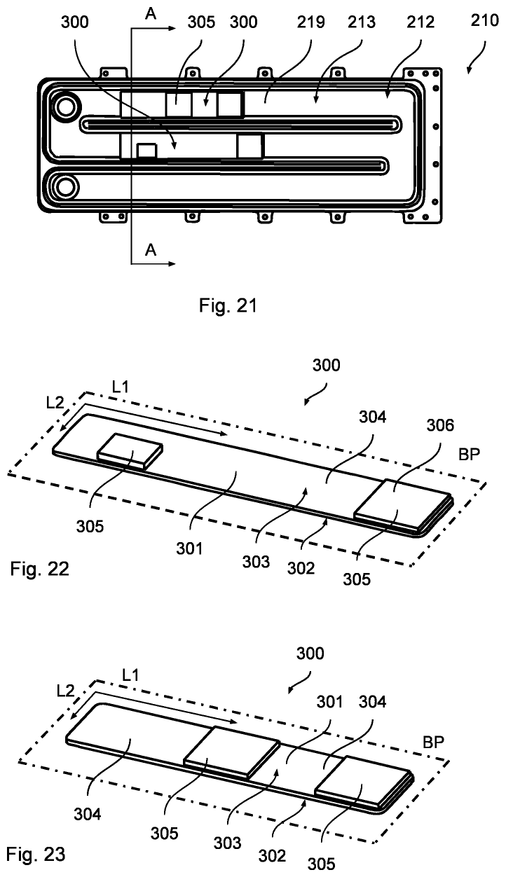

FIG. 21 shows an example of a first tube 210 with attachments 300. The first tube 210 includes the first shaped plate 212, which allows defining the first tube channel 2103 together with the first flat plate 211. In general, the first tube channel 2103 can have a channel wall 219 formed by any heat exchange plate 201, in this case the first shaped plate 212. One or more attachments 300 can be attached to that channel wall 219. The attachment 300 generally has a bottom side 302 and a top side 303 (as shown in FIG. 23). The attachment 300 can be connected to the channel wall 219 by the bottom side 302.

The attachment 300 can have a single contact portion 305 or a plurality of contact portions 305 extending away from a top side 303, preferably independently from each other. By a contact portion 305 it is here understood a dedicated part of the attachment 300 intended to be in contact with a specific heat source so that heat can be exchanged therebetween in a facilitated manner. It is intended for the contact portion 305 to receive bulk of the energy from the heat source as opposed to sections of the attachment 300 where contact portion 305 is not present.

As shown in FIGS. 20-28, the attachment 300 has an attachment base plate 301 extending within a base plane BP. A thickness T is defined as extending between the bottom side 302 and the top side 303 between of the attachment base plate 301. The attachment base plate 301 can be of rectangular, elongated outline extending along an attachment longitudinal axis L1 and an attachment lateral axis L2, the extension along the attachment longitudinal axis L1 being predominant.

FIG. 22 shows an example of an attachment 300, with two contact portions 305. Contact portions 305 extend away from the top side 303 perpendicularly to the base plane BP.

In one embodiment, the attachment base plate 301 and the contact portions 305 are a single machined piece. Alternatively, the contact portions 305 can be connected to the attachment base plate 301 by means of an adhesive. Preferably, the plurality of contact portions 305 are made of a solid material. Preferably, the attachment 300 is made of a material of high thermal conductivity. Preferably, the attachment 300 and the contact portions 305 are made of metal. In such case, the contact portions 305 can be connected to the attachment base plate 301 by brazing.

In the shown embodiment, there is a distancing section 304 between the contact portions 305. Here, the distancing section 304 is a region of the base plate 301, in particular of its top side 303, where the contact portions 305 are not present. The distancing section 304 can allow to reduce the amount of material needed for the attachment 300 in areas more remote with respect to heat sources than the contact portions 305. The distancing sections 304 however, in particular the region of the attachment base plate 301 at its bottom side 302, can contribute to secure connection of the attachment 300 to any heat exchange plate 201 (in these cases a first flat plate 211, a first shaped plate 212, a second flat plate 221, a second shaped plate 222), as sufficient contact surface between the attachment 300 and said heat exchange plate 201 is ensured.

In any case, it is preferable for the contact portions 305 to have a contact surface adapted for intermediate surface of a heat source that they are intended to face to maximize heat exchange efficiency. Preferably, the contact portions 305 have flat top contact surface 306, especially when they are matched with integrated circuits, which themselves tend to have flat surfaces.

Any contact portion 305 can have a rectangular outline, e.g. square outline (as shown in FIGS. 21, 22) or a rounded outline, e.g. oval or circular (as shown in FIG. 26), the outline extending in its width and length dimensions.

FIG. 23 shows another example of an attachment 300. In this case, the two contact portion 305 are identical to each other and are separated by a distancing section 304. It is worth noting that the distancing section 304 can be present between any contact portion 305 and an edge of the attachment base plate 301, not only strictly between the contact portions 305.

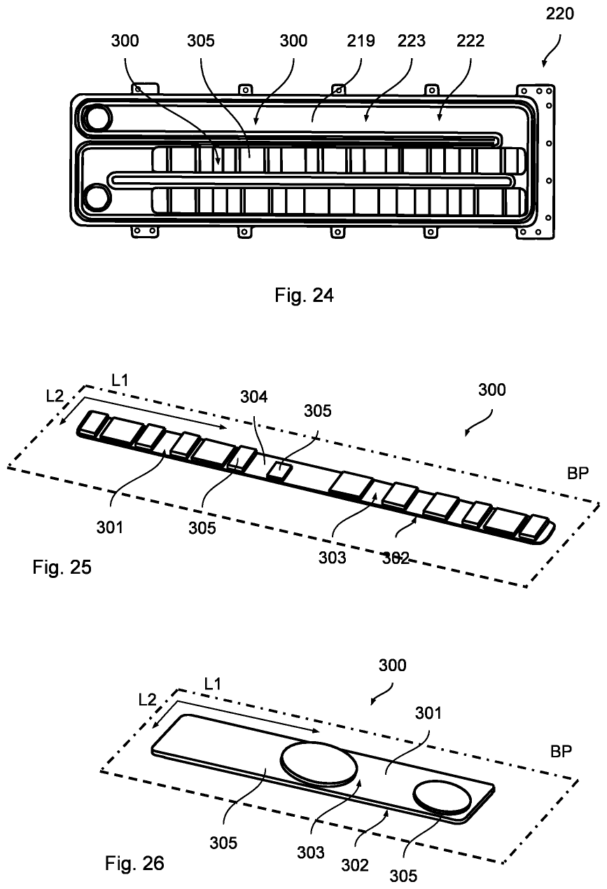

FIG. 24 shows an example of a second tube 220 with attachments 300. The second tube 220 includes the second shaped plate 222, which allows defining the second tube channel 2203 together with the second flat plate 221. In general, the second tube channel 2203 can have a channel wall 219 formed by any heat exchange plate 201, in this case the second shaped plate 222. One or more attachments 300 can be attached to that channel wall 219, for example analogously to how it was described earlier in relation to the first tube 210.

FIG. 25 shows another example of an attachment 300. In this case, the attachment 300 for a second tube 220 is presented, including a plurality of contact portions 305. The presented contact portions 305 can differ from each other in terms of size and shape to accommodate differently shaped and sized heat sources, in this case the third heat sources 431. The nature of envisaged differentiation will be explained in relation to following figures.

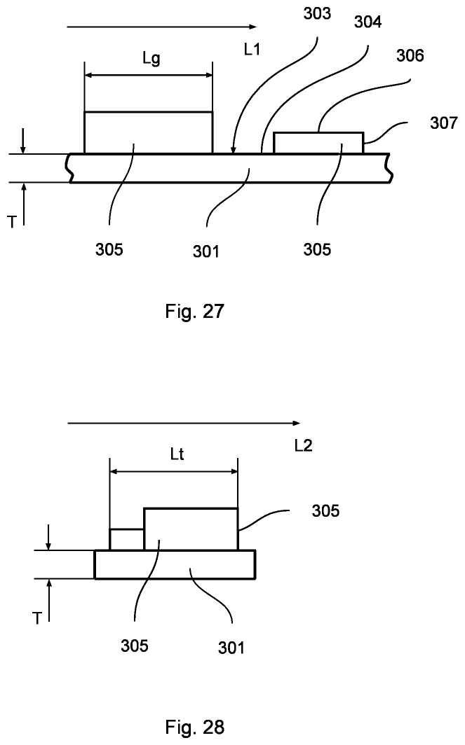

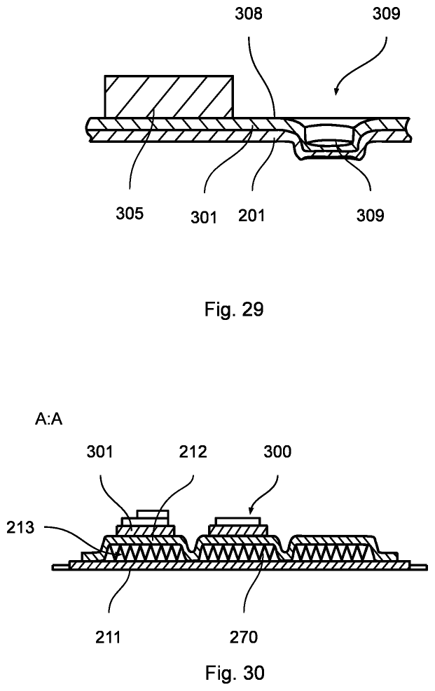

FIG. 27 shows schematically a partial side view of an attachment 300 of FIG. 25 in detail. The top side 303 can have a distancing section 304 between neighboring contact portions 305, the distancing section 304 maintaining the thickness T.

In one embodiment, at least one contact portion 305 extends from the attachment base plate 301 farther than another contact portion 305. In other words, one contact portion 305 can have different height than another contact portion 305.

In one embodiment, at least one contact portion 305 has a different longitudinal length Lg than another contact portion 305, the longitudinal length Lg being measured along the attachment longitudinal axis L1.

The top side 303 of the attachment base plate 301 and the flat top contact surfaces 306 of the contact portions 305 can be connected by side walls 307 of the contact portions 305, the side walls 307 being perpendicular to the top side 303 and the flat top contact surfaces 306. Alternatively, the side walls 307 can be oblique with respect to the top side 303 and/or the flat top contact surfaces 306.

FIG. 28 shows schematically another side view of an attachment 300 in detail of FIG. 25 in detail. At least one contact portions 305 can have a different lateral length Lt than another contact portion 305, the lateral length Lt being measured along the attachment lateral axis L2.

FIG. 27 shows schematically an example of a partial cross-sectional view of a heat exchange plate 201 with an attachment 300. The attachment base plate 301 can have connection section 308 adapted for clinching. As explained earlier, the top side 303 of the attachment base plate 301 can have a distancing section 304 between the contact portions 305, the distancing section 304 maintaining the thickness T of the attachment base plate 301. The attachment base plate 301 can be clinched to the channel wall 219 of any heat exchange plate 201 (e.g. the first flat plate 211, the first shaped plate 212, the second flat plate 221, the second shaped plate 222) at the distancing section 304 by a clinched connection 309. Such clinched connection 309 may be an intermediate step for connecting the attachment 300 to any heat exchange plate 201, which subsequently can be finally fixed by means of brazing. In such case, the clinched connection 309 serves to position the components in relation to one another so that the brazing process can be efficiently performed.

FIG. 30 shows a cross-section view of the first tube 210 of FIG. 20. A turbulator 270 for improving heat exchange efficiency can be placed within the first tube channel 2103. It can be present in select arms 214 or conduits 217 or sub-conduits 216 of the first tube channel 2103, or can fill them all at the same time. The same applies mutatis mutandis to the second tube 220 or other tubes if present.

FIGS. 31 and 32 show another example a heat exchanger 200 in exploded views respectively from above and below. The heat exchanger 200 comprises a first tube 210 with a first tube inlet 2101 and a first tube outlet 2102 interconnected by a first tube channel 2103 and a second tube 220 with a second tube inlet 2201 and a second tube outlet 2202 interconnected by a second tube channel 2203. The interconnector 260 includes an upper face 2610 and a lower face 2620. The upper face 2610 faces the first tube 210, while the lower face 2620 faces the lower tube 220.

The interconnector 260 is connected to the first tube inlet 2101 by an upper inlet 2611 and to the first tube outlet 2102 by the upper outlet 2614. The interconnector 260 is connected to the second tube inlet 2201 by the lower inlet 2621 and to the second tube outlet 2202 by the lower outlet 2624.

The interconnector 260 can be located between the first tube 210 and the second tube 220. Preferably, the interconnector 260 is located at the ends of the first tube 210 and the second tube 220.

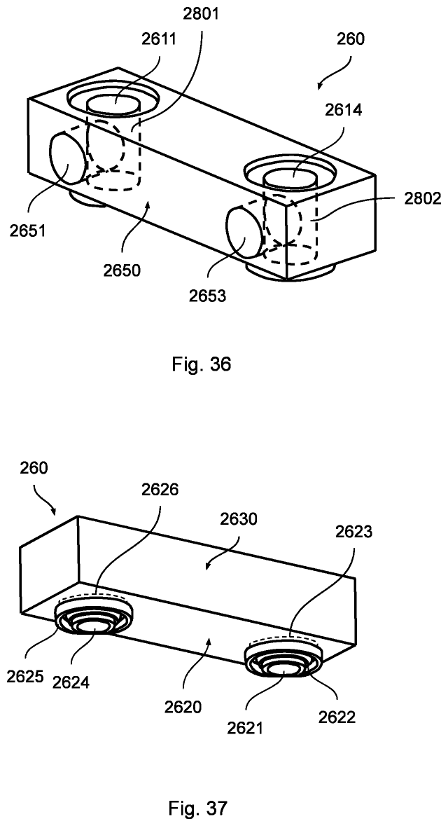

The interconnector 260 includes a body 261 with an upper inlet 2611 and a lower inlet 2621 connected by an inlet conduit 2801 (as shown in FIG. 36). The body 261 includes an upper outlet 2614 and a lower outlet 2624 connected by an outlet conduit 2802. The body 261 also includes an external inlet 2651 communicated with the inlet conduit 2801 and an external outlet 2653 communicated with the outlet conduit 2802.

The external inlet 2651 can face away from the first tube 210 and the second tube 220.

The interconnector 260 has an upper inlet collar 2613 inserted into an upper inlet collar opening 2612 of the interconnector 260. The upper inlet collar 2613 connects the upper inlet 2611 with the first tube inlet 2101.

In this embodiment, the interconnector 260 has an integrated lower inlet collar 2622 connecting the lower inlet 2621 with the second tube inlet 2201.

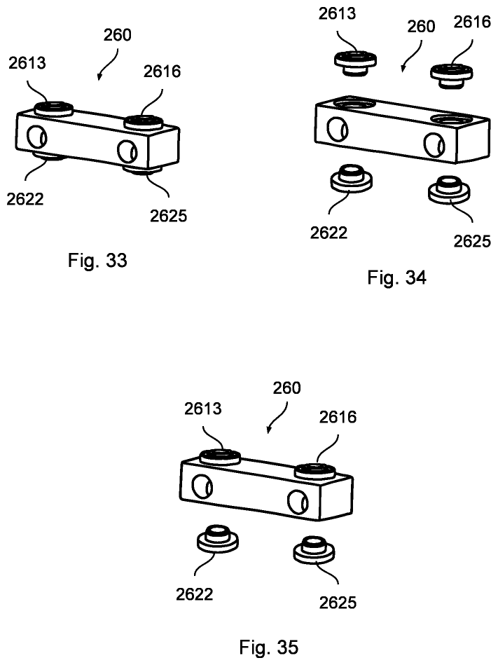

FIG. 33 shows an example of an interconnector 260 from the front.

FIG. 34 shows another example of an interconnector 260 in an exploded view from the front.

FIG. 35 shows another example of an interconnector 260 in an exploded view from the front.

FIG. 36 shows an example of an interconnector 260 with visualized inner channels, while FIG. 37 shows an example of an interconnector 260 from the back. The interconnector 260 includes an internal face 2630, facing a space between the first tube 210 and the second tube 220.

In the shown embodiment, the upper inlet 2611 and the lower inlet 2621 are concentric. In the shown embodiment, the upper outlet 2614 and the lower outlet 2624 are concentric. Preferably, the external inlet 2651 is arranged perpendicular to the upper inlet 2611. Preferably, the external outlet 2653 is arranged perpendicular to the upper outlet 2614. Preferably, the external inlet 2651 is arranged parallel to the external outlet 2653.

The inlet conduit 2801 and the outlet conduit 2802 are fluidically isolated with respect to each other within the interconnector 260.

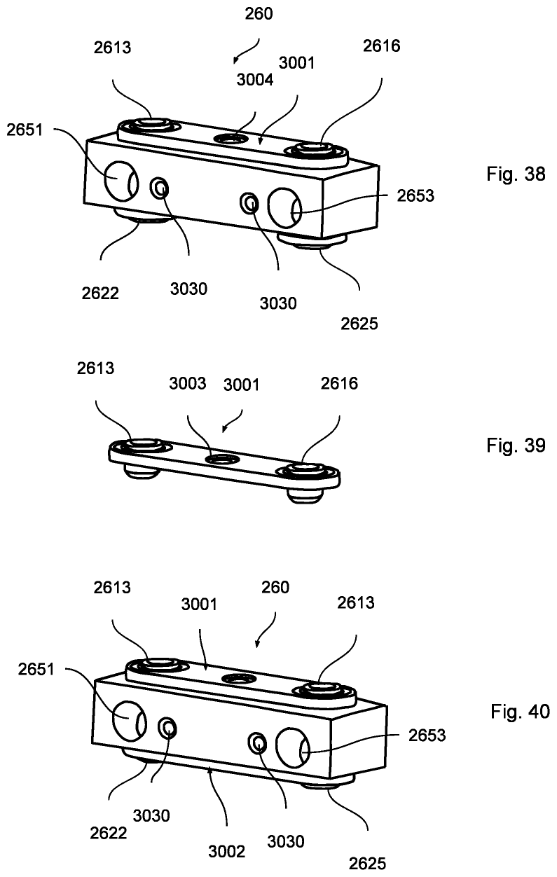

FIG. 38 shows another example of an interconnector 260 from the front. An upper collar plate 3001, with an integrated upper inlet collar 2613 and an integrated upper outlet collar 2616, is attached to the interconnector 260. The upper inlet collar 2613 is inserted into the upper inlet collar opening 2612 of the interconnector 260 and connecting the upper inlet 2611 with the first tube inlet 2101. The upper outlet collar 2616 is inserted into an upper outlet collar opening 2615 of the interconnector 260 and connecting the upper outlet 2614 with the first tube outlet 2102. The upper collar plate 3001 can be connected to the interconnector 260 by means of a collar plate screw 3004 (screwed into a screw hole in the interconnector 260, not shown here). The interconnector 260 can include connector screw holes 3030 for connecting by means of screws any inlet and outlet connectors.

FIG. 39 shows the collar plate 3001 of an interconnector 260, with a collar plate screw hole 3003.

FIG. 40 shows another example of an interconnector 260 from the front. A lower collar plate 3002, with an integrated lower inlet collar 2622 and an integrated lower outlet collar 2625, is attached to the interconnector 260. The lower inlet collar 2622 is inserted into a lower inlet collar opening 2623 of the interconnector 260 and connects the lower inlet 2621 with the second tube inlet 2201. The lower outlet collar 2625 is inserted into a lower outlet collar opening 2626 of the interconnector 260 and connects the lower outlet 2624 with the second tube outlet 2202.

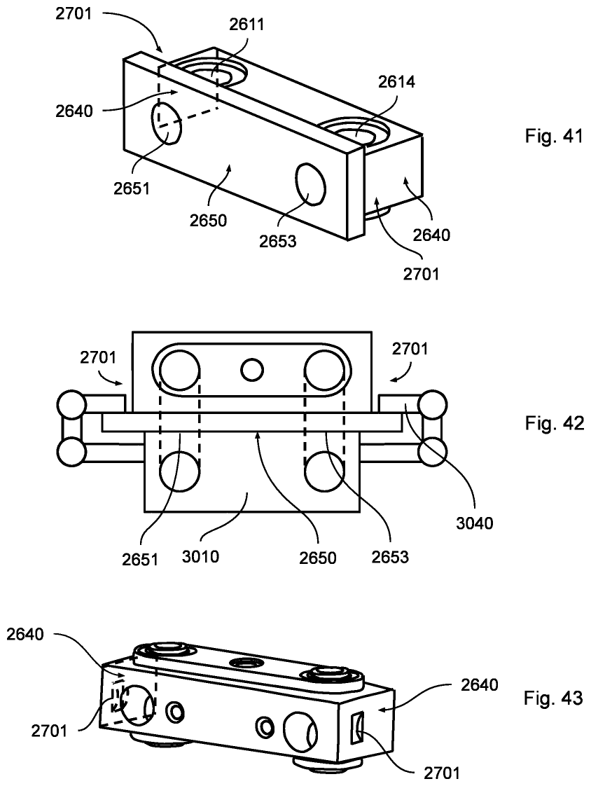

FIG. 41 shows another example of an interconnector 260 from the front. The body 261 includes a first external face 2650 and two lateral faces 2640 arranged at the sides of the first external face 2650. The external inlet 2651 and the external outlet 2653 are located on the first external face 2650. Each of the two lateral faces 2640 includes a first recess 2701 for anchoring a first external connector 3010 to the first external face 2650.

FIG. 42 shows the interconnector of FIG. 41 with a first external connector 3010 from the top. Connector arms 3040 can be seen being inserted into the first recesses 2701 for firmly attaching the first external connector 3010.

FIG. 43 shows another example of an interconnector 260 from the front.

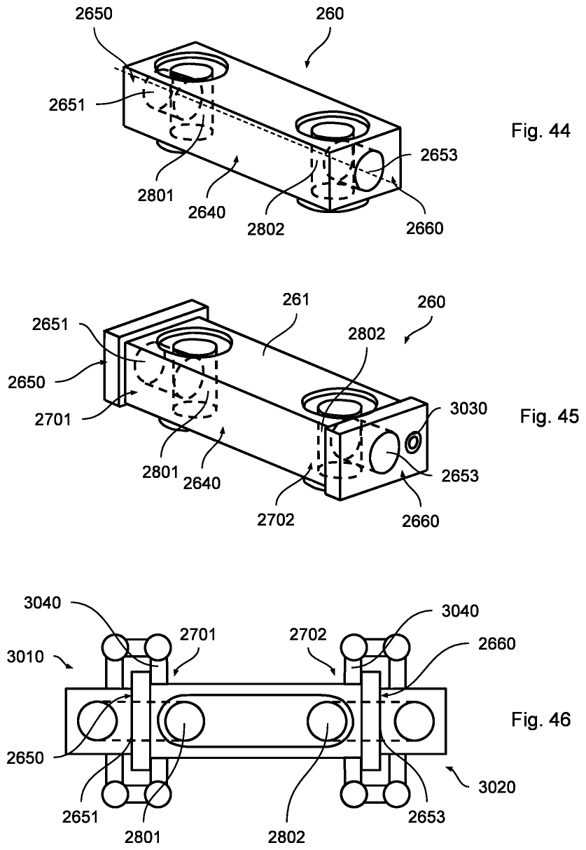

FIG. 44 shows another example of an interconnector 260 with visualized inner channels. The external inlet 2651 can face away from the external outlet 2653. The external inlet 2651 can be concentric with the external outlet 2653. In other words, central axes of the external inlet 2651 and the external outlet 2653 are collinear

FIG. 45 shows another example of an interconnector 260 from the front. The body 261 includes a first external face 2650 on which the external inlet 2651 is arranged. The body 261 includes also a second external face 2660 on which the external outlet 2653 is arranged. The body 261 includes further two lateral faces 2640 arranged at the sides of the first external face 2650 and the second external face 2660. Each of the two lateral faces 2640 includes a first recess 2701 for anchoring a first external connector 3010 to the first external face 2650 and a second recess 2702 for anchoring a second external connector 3020 to the second external face 2660.

FIG. 46 shows the interconnector of FIG. 45 with two external connectors 3001, 3002 from the top. The connector arms 3040 of the first external connector 3010 are placed in the first recesses 2701, while the connector arms 3040 of the second external connector 3020 are placed in the second recesses 2702.

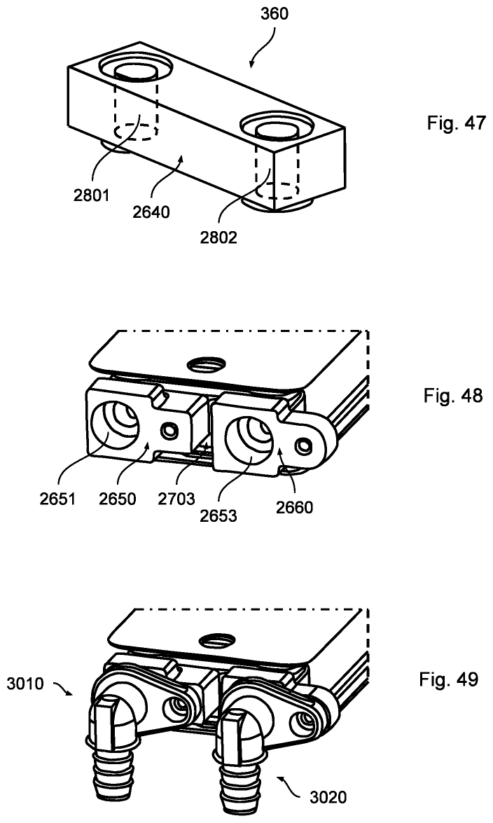

FIG. 47 shows example of an additional interconnector 360. In this example, the additional interconnector 360 has only blank lateral walls 2640 with no external inlets and outlets.

FIG. 48 shows another example of a heat exchanger in a perspective view, while FIG. 49 shows the heat exchanger of FIG. 48 with external connectors 3010, 3020. Preferably, the body 261 includes a first external face 2650 on which the external inlet 2651 is arranged and a second external face 2660 on which the external outlet 2653 is arranged. A middle recess 2703 is arranged between the first external face 2650 and the second external face 2660 and is extending between the inlet conduit 2801 and the outlet conduit 2802.

The interconnector 260 as shown is a rigid element enabling secure and stable connection to any external connectors 3001, 3002. Additionally, the interconnector 260 serves as a rigid element to interconnect the tubes 210, 220, 230 of the heat exchanger 200. Such interconnector 260 is easy to manufacture and adapt according to needs. It can serve as a standalone attachment point for the external connectors 3001, 3002.

Thank to appropriate placement and dimensioning of the recesses 2701, 2702, 2703, 2704, 2705, the interconnector 260 can be configured to be placed partially or wholly between the tubes 210, 220 or 230.

In case of separately provided collar plates 3001, 3002 the body 261 can be less complicated and easier to manufacture.

Other variations to the disclosed embodiments can be understood and effected by those skilled in the art in practicing the claimed invention, from a study of drawings, the disclosure, and the appended claims. The mere fact that certain measures are recited in mutually different dependent claims does not indicate that a combination of these measures cannot be used to the advantage.

1. An interconnector for a heat exchanger comprising
a body with
an upper inlet and a lower inlet connected by an inlet conduit,
an upper outlet and a lower outlet connected by an outlet conduit,
an external inlet communicated with the inlet conduit,
an external outlet communicated with the outlet conduit,
wherein the inlet conduit and the outlet conduit are fluidically isolated with respect to each other within the interconnector.

2. The interconnector according to claim 1, wherein the upper inlet and the lower inlet are concentric.

3. The interconnector according to claim 1, wherein the upper outlet and the lower outlet are concentric.

4. The interconnector according to claim 1, wherein the external inlet is arranged perpendicular to the upper inlet.

5. The interconnector according to claim 1, wherein the external outlet is arranged perpendicular to the upper outlet.

6. The interconnector according to claim 1, wherein the external inlet is arranged parallel to the external outlet.

7. The interconnector according to claim 1, wherein the external inlet faces away from the external outlet.

8. The interconnector according to claim 1, wherein central axes of the external inlet and the external outlet are collinear.

9. The interconnector according to claim 1, wherein the body includes a first external face on which the external inlet is arranged, a second external face on which the external outlet is arranged, and a middle recess arranged between the first external face and the second external face and extending between the inlet conduit and the outlet conduit.

10. The interconnector according to claim 1, wherein the body includes an upper face with an upper recess, the upper inlet and the upper outlet being arranged within the upper recess.

11. The interconnector according to claim 1, wherein the body includes a lower face with a lower recess, the lower inlet and the lower outlet being arranged within the lower recess.

12. A heat exchanger comprising:
a first tube with a first tube inlet and a first tube outlet interconnected by a first tube channel;
a second tube with a second tube inlet and a second tube outlet interconnected by a second tube channel;
an interconnector having
a body with
an upper inlet and a lower inlet connected by an inlet conduit,
an upper outlet and a lower outlet connected by an outlet conduit,
an external inlet communicated with the inlet conduit,
an external outlet communicated with the outlet conduit;
wherein the inlet conduit and the outlet conduit are fluidically isolated with respect to each other within the interconnector,
the interconnector being located between the first tube and the second tube,
the interconnector being connected to the first tube inlet by the upper inlet and to the first tube outlet by the upper outlet,
the interconnector being connected to the second tube inlet by the lower inlet and to the second tube outlet by the lower outlet.

13. The heat exchanger according to claim 11, wherein the external inlet faces away from the first tube and the second tube.

14. The heat exchanger according to claim 11, wherein the external outlet faces away from the first tube and the second tube.

15. The heat exchanger according to claim 11, wherein the interconnector has an upper inlet collar inserted into an upper inlet collar opening of the interconnector, the upper inlet collar connecting the upper inlet with the first tube inlet.

16. The heat exchanger according to claim 11, wherein the interconnector has an integrated lower inlet collar connecting the lower inlet with the second tube inlet.

17. The heat exchanger according to claim 11, wherein an upper collar plate, with an integrated upper inlet collar and an integrated upper outlet collar, is attached to the interconnector, the upper inlet collar being inserted into an upper inlet collar opening of the interconnector and connecting the upper inlet with the first tube inlet, with the upper outlet collar being inserted into an upper outlet collar opening of the interconnector and connecting the upper outlet with the first tube outlet.

18. The heat exchanger according to claim 11, wherein a lower collar plate, with an integrated lower inlet collar and an integrated lower outlet collar, is attached to the interconnector, the lower inlet collar being inserted into a lower inlet collar opening of the interconnector and connecting the lower inlet with the second tube inlet, with the lower outlet collar being inserted into a lower outlet collar opening of the interconnector and connecting the lower outlet with the second tube outlet.

19. The heat exchanger according to claim 11, wherein the interconnector is located at ends of the first tube and the second tube.

20. The heat exchanger according to claim 11, with the second tube including an additional second tube inlet and an additional second tube outlet interconnected by the second tube channel, the heat exchanger further comprising
a third tube with a third tube inlet and a third tube outlet interconnected by a third tube channel,
an additional interconnector including
a body with
an upper inlet and a lower inlet connected by an inlet conduit,
an upper outlet and a lower outlet connected by an outlet conduit,
wherein the inlet conduit and the outlet conduit are fluidically isolated with respect to each other within the additional interconnector,
the additional interconnector being located between the second tube and the third tube,
the additional interconnector being connected to the additional second tube inlet by the upper inlet of the additional interconnector and to the additional second tube outlet by the upper outlet of the additional interconnector,
the additional interconnector being connected to the third tube inlet by the lower inlet of the additional interconnector and to the third tube outlet by the lower outlet of the additional interconnector.

21. The heat exchanger according to claim 19, wherein the body of the additional interconnector includes an external inlet communicated with the inlet conduit of the additional interconnector and an external outlet communicated with the outlet conduit of the additional interconnector.
